(19) United States
(12) Patent Application Publication
(10) Pub. No.: US 2026/0305055 A1
(43) Pub. Date: Oct. 1, 2026

(54) FORMING PASSIVATION, ELECTRON TRANSPORT, AND HOLE BLOCKING LAYERS IN PEROVSKITE MODULES

(71) Applicant: Caelux Corporation, Baldwin Park, CA (US)

(72) Inventors: Mihirsinh Chauhan, Azusa, CA (US); Ali Desmond, Gardena, CA (US); Kasra Darabi, Duarte, CA (US); Gaurab J. Thapa, Azusa, CA (US); John Iannelli, San Marino, CA (US)

(21) Appl. No.: 19/629,991

(22) Filed: Mar. 26, 2026

Related U.S. Application Data
(60) Provisional application No. 63/778,253, filed on Mar. 26, 2025.
(60) Provisional application No. 63/778,228, filed on Mar. 26, 2025.

(51) Int. Cl. H10K 30/88; H10K 30/85; H10K 30/86; H10K 71/40; H10K 71/60; H10K 85/50

(52) U.S. Cl. CPC H10K 30/88; H10K 30/85; H10K 30/86; H10K 71/40; H10K 71/60; H10K 85/50

(57) ABSTRACT

A method for forming a perovskite solar cell includes: depositing a mixture comprising a sulfonium-based passivation material, a fullerene derivative, and a hole-blocking material on a surface of a substrate comprising a perovskite layer to form a single-step multifunctional layer; and further processing the substrate and the single-step layer to form a perovskite solar cell.

### CROSS-REFERENCE TO RELATED APPLICATIONS

This application is claims priority to Provisional Application No. 63/778,228, titled “SCALABLE SINGLE-STEP COATING APPROACH FOR PASSIVATION, ELECTRON TRANSPORT, AND HOLE BLOCKING LAYERS IN PEROVSKITE MODULES,” filed on Mar. 26, 2025, and to Provisional Application No. 63/778,253, titled “VACUUM QUENCHING FOR SOLVENT EXTRACTION FROM SOLUTION-PROCESSED CARRIER TRANSPORT LAYERS IN PRODUCTION OF PEROVSKITE-BASED DEVICES,” also filed on Mar. 26, 2025, the contents both of which are hereby incorporated by reference.

### FIELD OF THE INVENTION

The present disclosure relates to the fabrication of perovskite solar cells (PSC)/modules, particularly methods for improving the scalability, uniformity, and performance of perovskite modules. More specifically, the disclosed technology involves one-step coating processes to apply a passivation, electron transport, and hole-blocking layer (PEH) by mixing, e.g., a sulfonium-based passivation, fullerene derivative, hole blocking layer for large-area substrate manufacturing.

### BACKGROUND

Perovskite solar cells have shown great promise for solar energy conversion due to their high efficiency and low-cost fabrication. However, the scalability of the current manufacturing methods poses challenges, particularly when transitioning from small area research and development (R&D) scale to large area industrial-scale production. In particular, in small-scale research and development (R&D) processes, perovskite solar cells (PSCs) are commonly fabricated using a three-step coating process involving a surface passivation layer (P), an electron transport layer (E), and a hole-blocking layer (H). While these methods can be effective in achieving high efficiency and stability, they present challenges in terms of scalability for large-scale industrial production. The need for multiple coating steps increases complexity, processing time, and material consumption, making it impractical for high-throughput manufacturing.

In addition, performance degradation in PSCs is often initiated at grain boundaries and interfaces, where defects and mobile ions tend to accumulate. These regions are particularly susceptible to external stressors such as continuous illumination, humidity, and elevated temperatures. Effective interface engineering is therefore important to suppress surface defects and inhibit mobile ion migration, which can otherwise lead to degradation and performance loss.

To address these challenges, various passivation agents, such as ammonium-based salts, small organic molecules, and polymers, have been considered. For example, sulfonium base passivation using dimethylphenethylsulfonium iodide (DM), a sulfonium-based aprotic molecule, has been explored as a promising post-deposition treatment. Sulfonium base passivation has demonstrated potential in stabilizing PSCs by reducing performance loss and enhancing long-term stability. For example, DM-treated perovskite solar cells exhibit less than 1% performance loss after more than 4,500 hours of maximum power point tracking, with a theoretical T80 lifetime of over nine years under continuous 1-sun illumination. However, applying passivation layer as a separate layer in large-scale production can be difficult and costly, an may limit its practicality for commercial applications In addition, depending on the device architecture (N-I-P or P-I-N), the hole transport layer and electron transport layer function as the p-type and n-type contacts, respectively, deposited on top of the passivation layer. Finally, an electron or hole blocking layer (depending on device architecture) is introduced to prevent the migration of charge carriers toward the electrodes and to minimize interfacial recombination.

These layers are typically deposited using a variety of methods such as physical vapor deposition (PVD) (evaporation, sputtering, atomic layer deposition, etc.) as well as solution-based wet processing techniques. While PVD techniques lend themselves to scalable large-area depositions, not all materials are compatible with PVD techniques. Many of the organic transport layer materials are typically deposited using solution-based techniques. Depositing these solutions on large area devices can be carried out with several techniques including spray deposition, roll coating, slot-die coating, and blade coating. For solution-based processes, wet film formation is generally the first fabrication step. The second step is the removal of the solvent such that a solid film is formed with necessary thickness and uniformity. The solvent removal can be accomplished using thermal evaporation, spin coating, or air knife extraction.

### SUMMARY

Perovskite solar cells generally feature a multilayer structure including a substrate, one or more electrodes, a perovskite absorber layer, and charge transport layers positioned on opposite sides of the absorber. The charge transport layers typically include an electron transport layer (ETL) and a hole transport layer (HTL), which facilitate selective extraction and transport of electrons and holes, respectively. In addition, a passivation layer may be applied at the perovskite interface to reduce surface defects, suppress non-radiative recombination, and improve device stability.

The present disclosure relates to scalable fabrication methods and device architecture for perovskite solar cells and perovskite photovoltaic modules. More specifically, the disclosure describes methods for forming a composite interfacial layer including a passivation material, an electron transport material, and a hole-blocking material that can be deposited using fewer processing steps than conventional methods, thereby improving manufacturability and scalability for large-area photovoltaic devices. To address certain limitations of conventional multi-step deposition of passivation, transport, and blocking layers, namely increased process complexity, extended fabrication time, and higher material consumption, the present disclosure introduces a composite interfacial layer that integrates passivation, electron transport, and hole-blocking functionalities into fewer coating steps, thereby enabling a more scalable and cost-effective manufacturing approach.

In conventional fabrication approaches, the passivation layer, electron transport layer, and hole-blocking layer are deposited as separate layers using multiple sequential coating or deposition steps. These sequential processes are commonly employed in research-scale device fabrication, particularly for small-area devices fabricated using spin coating. While such methods can be effective for optimizing device performance at laboratory scale, they present challenges for industrial-scale production due to, e.g., increased process complexity, longer fabrication times, and/or greater material consumption.

The present disclosure addresses these challenges by introducing a composite interfacial layer that integrates passivation, electron transport, and hole-blocking functionalities into a reduced number of coating steps for P-I-N device structure. In certain implementations, a single solution mixture including passivation materials, fullerene derivative electron transport materials, and hole-blocking layer materials is prepared and deposited onto the perovskite absorber layer in a single coating step. This unified layer may be referred to as a PEH layer, representing the combination of passivation (P), electron transport (E), and hole-blocking (H) materials.

In some implementations, the passivation component includes a sulfonium-based compound capable of chemically interacting with defect sites present at the perovskite surface or grain boundaries. For example, sulfonium salts such as dimethylphenethylsulfonium iodide (DM), trimethylsulfonium bromide (TMSBr), 2-(carboxyethyl) (dimethyl) sulfonium bromide (CDMSBr), trimethylsulfonium lead triiodide (TMSPbI₃), trimethylsulfoxonium lead triiodide (TMSOPbI₃), may be employed to passivate under-coordinated ions and reduce defect densities at the perovskite interface. Such passivation materials may improve device stability and reduce performance degradation under prolonged illumination or environmental stress compared to similar devices that don't include a passivation material.

The electron transport component can include fullerene derivatives that facilitate efficient electron extraction and transport from the perovskite absorber layer toward the cathode electrode. In certain examples, the electron transport material includes phenyl-C61-butyric acid methyl ester (PCBM) or related fullerene derivatives. These materials may provide suitable energy level alignment with the perovskite absorber layer and may assist in reducing recombination losses at the interface.

The hole-blocking component can include materials capable of selectively blocking hole transport while allowing electrons to pass toward the cathode. The hole-blocking layer may also serve to protect the underlying electron transport layer from damage during subsequent electrode deposition processes, such as physical vapor deposition (PVD) of metal electrodes. In certain examples, the hole-blocking material may include bathocuproine (BCP), bathophenanthroline (BPhen), and/or other suitable organic materials capable of forming a thin interfacial barrier.

In some implementations, the passivation material, electron transport material, and hole-blocking material are dissolved in a suitable solvent, e.g., a single solvent or solvent mixture, to form a coating solution. Example solvents include anisole, chlorobenzene, dichlorobenzene, toluene, chloroform, or combinations thereof. These solvents are commonly used in solution-processed organic electronic materials due to their compatibility with fullerene derivatives and other organic transport materials.

The composite passivation, electron transport, and hole-blocking layer (PEH) solution may be deposited onto the perovskite absorber layer using a variety of coating techniques. In research-scale fabrication, spin coating may be used to deposit the layer. However, for large-area module manufacturing, scalable coating techniques such as slot-die coating, blade coating, spray coating, roll coating, or other continuous deposition methods may be employed.

Following deposition of the wet film, the solvent is removed to form a uniform solid film with suitable thickness and morphology. In conventional processing methods, solvent removal may be achieved through thermal annealing, air drying, or other evaporation-based processes. However, uniform solvent removal across large-area substrates may be challenging when relying solely on thermal methods. To address this challenge, a vacuum-quenching method can be used for rapid and uniform solvent extraction. In this method, a vacuum environment is established above the wet film shortly after deposition. The reduced pressure environment lowers the effective boiling point of the solvent and accelerates solvent evaporation from the film. This process promotes rapid crystallization and solidification of the composite PEH layer across the entire substrate area.

The vacuum-quenching process can offer several advantages for large-area device fabrication. First, solvent removal can occur simultaneously across the entire device surface when performed in a sufficiently large vacuum chamber. Second, the reduced pressure environment enables solvent extraction at relatively low temperatures, reducing thermal stress on the perovskite layer and minimizing flammability risks associated with high-temperature processing. Third, the rapid solvent removal enabled by vacuum quenching can shorten processing times and increase manufacturing throughput.

In certain aspects, the present disclosure addresses the technical problem of performance degradation and manufacturing complexity in perovskite solar cells. Conventional multi-step deposition of separate passivation, transport, and blocking layers can lead to increased material consumption, extended fabrication times, and interfacial defects due to multiple solvent exposure cycles.

To solve this problem, the disclosed methods can employ a single-step deposition of a composite mixture containing a sulfonium-based passivator, a fullerene derivative, and a hole-blocking material. This provides the technical effect of simultaneously passivating surface defects, facilitating electron extraction, and providing a protective barrier against subsequent electrode deposition. Furthermore, the use of vacuum quenching for solvent extraction allows for rapid, low-temperature solidification across large areas. This results in improved film uniformity and enhanced thermal and moisture stability compared to conventionally processed layers, while significantly increasing manufacturing throughput.

Various aspects of the disclosure are summarized as follows:
In general, in a first aspect, the disclosure features a method for forming a perovskite solar cell, including: depositing a mixture comprising a sulfonium-based passivation material, a fullerene derivative, and a hole-blocking material on a surface of a substrate comprising a perovskite layer to form a single-step multifunctional layer; and further processing the substrate and the single-step layer to form a perovskite solar cell.
Implementations of the method can include one or more of the following features. For example, the sulfonium-based passivation can chemically passivate under-coordinated lead sites and halide vacancies in the perovskite layer.

The fullerene derivative can form a percolated electron transport pathway for efficient electron extraction from the perovskite absorber.

The hole-blocking material can be selected from the group composed of BCP, BPhen, or derivatives thereof.

The mixture can be dissolved in one or more organic solvents selected from anisole, chlorobenzene, dichlorobenzene, toluene, or chloroform.

The mixture can be deposited using a solution-processing technique selected from spin coating, slot-die coating, blade coating, spray coating, or roll-to-roll coating.

The method can include exposing the deposited mixture to a vacuum to control solvent evaporation, wherein the vacuum pressure is in a range of 1 Torr to 700 Torr. The vacuum can be applied uniformly across the coating or according to a spatial extraction profile to achieve uniform film formation. The vacuum can be applied via a showerhead manifold comprising a plurality of nozzles arranged to provide a non-uniform spatial extraction profile to compensate for edge-effect evaporation.

The processing can include thermal annealing of the deposited layer to improve crystallinity of the electron transport and passivation mixture.

The deposition and processing of the single-step layer simultaneously can achieves one or more of surface passivation of the perovskite layer, efficient electron extraction, and hole-blocking functionality.

The single-step layer can reduce dimerization of the fullerene derivative and suppresses triplet-to-singlet recombination at the interface.

The method can include forming a top electrode by physical vapor deposition (PVD), wherein the single-step layer protects the electron transport layer from plasma-induced damage during electrode deposition.

In general, in another aspect, the disclosure features a perovskite solar cell, including: a perovskite absorber layer; a single-step interfacial layer deposited on the perovskite absorber, including a sulfonium-based passivation material, a fullerene derivative, and a hole-blocking material; and an electrode deposited on the single-step layer, wherein the single-step layer simultaneously provides chemical passivation, electron transport, and hole blocking.

Embodiments of the perovskite solar cell can include one or more of the following features. For example, the single-step layer can provide enhanced moisture and thermal stability by forming a hydrophobic interfacial barrier.

The single-step layer can suppresses ion migration at the ETL interface, improving operational and light-soaking stability.

The hole-blocking material can form a protective buffer between the electron transport layer and the top electrode to reduce, e.g., prevent, plasma- or energetic particle-induced damage.

The active area of the perovskite solar cell can be at least 100 cm², e.g., suitable for mini-module or industrial-scale module fabrication (e.g., >1.5 m²).

Other features and advantages will be apparent from the drawings, the description, and the claims.

### BRIEF DESCRIPTION OF THE DRAWINGS

FIGS. 1(a)-1(d) are schematic diagrams of various perovskite solar cell architectures including (a) a conventional three-layer stack, (b) a two-step stack, (c) a mixed ETL/HBL stack, and (d) a single-step PEH architecture.

FIG. 2 is a conceptual flow diagram illustrating methods for mixing passivation, electron transport, and hole-blocking materials in solution.

FIG. 3 shows spatially resolved photoluminescence (SRPL) comparisons for different device configurations.

FIGS. 4(a)-4(c) are time-resolved photoluminescence (TRPL) plots comparing charge extraction dynamics between conventional and single-step layers.

FIGS. 5(a)-5(b) are schematic diagrams of crystallization approaches including (a) thermal annealing and (b) vacuum quenching.

FIGS. 6(a)-6(b) are current-voltage (I-V) curves for two-step and single-step transport layer configurations.

FIG. 7 is a plot of power conversion efficiency (PCE) for various layer configurations.

FIGS. 8(a)-8(d) illustrate the vacuum-quenching approach and corresponding performance data as a function of vacuum level.

FIG. 9 is an I-V plot for a mini-module employing a single-step PEH layer.

FIG. 10 is a reliability plot comparing thermal stability between standard three-step and single-step configurations.

FIGS. 11(a)-11(b) illustrate I-V characteristics and efficiency distributions for industrial-scale perovskite modules.

FIG. 12 is a functional block diagram illustrating the dual chemical and physical roles of the single-step PEH layer.

### DETAILED DESCRIPTION

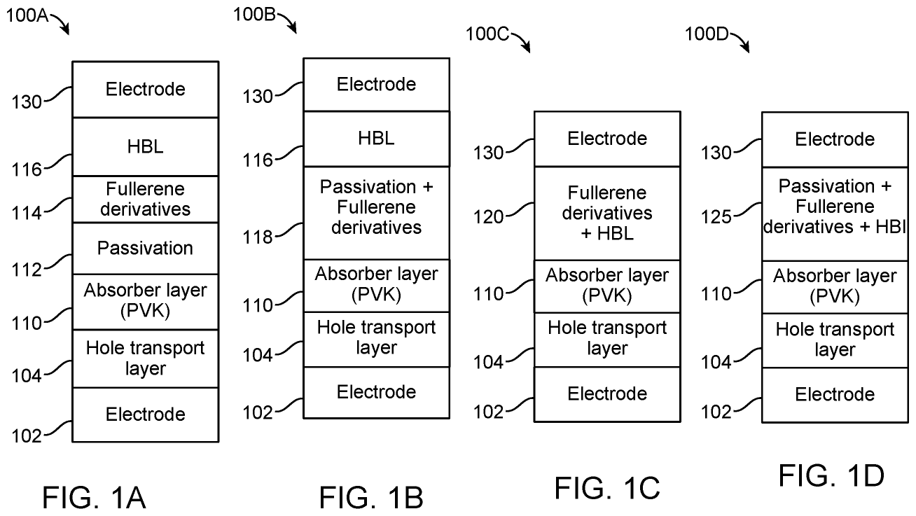

Various perovskite solar cell device architectures are shown schematically in FIGS. 1(a)-1(d). Each architecture includes a bottom electrode later 102, a hole transport layer 104, and a perovskite absorber layer 110. Each architecture also includes a top electrode 130. FIG. 1(a) shows a conventional multilayer architecture cell 100A that includes three separate solution-processed layers deposited sequentially on top of the perovskite absorber layer 110. In particular, architecture 100A includes a passivation layer 112 directly on PVK layer 110, then a fullerene derivative layer 114 on top of passivation layer 112, and then a hole blocking layer (HBL) 116 on top of the layer 114. In some examples, the hole transport layer 104 is a metal oxide, such as sputtered nickel oxide (NiO). In certain examples, the passivation layer 112 is a polymer, such as PMMA. The top electrode 130 is provided on the HBL 116.

FIG. 1(b) shows another multilayer architecture cell 100B. This architecture corresponds to a two-step solution-processed configuration in which a combined passivation layer and electron transport layer (ETL) 118 based on fullerene derivatives are deposited on the PVK 110, followed by the separate HBL 116.

FIG. 1(c) shows a further multilayer architecture cell 100C which is a single-step solution-processed configuration in which fullerene derivatives and the hole-blocking layer (HBL) are deposited as a mixed layer 120 on the PVK layer 110.

FIG. 1(d) shows a single-step solution-processed configuration, cell 100D, that includes a mixture of passivation material, fullerene derivatives electron transport material, and hole-blocking layer (HBL) 125 deposited together on the perovskite absorber (PVK) 110.

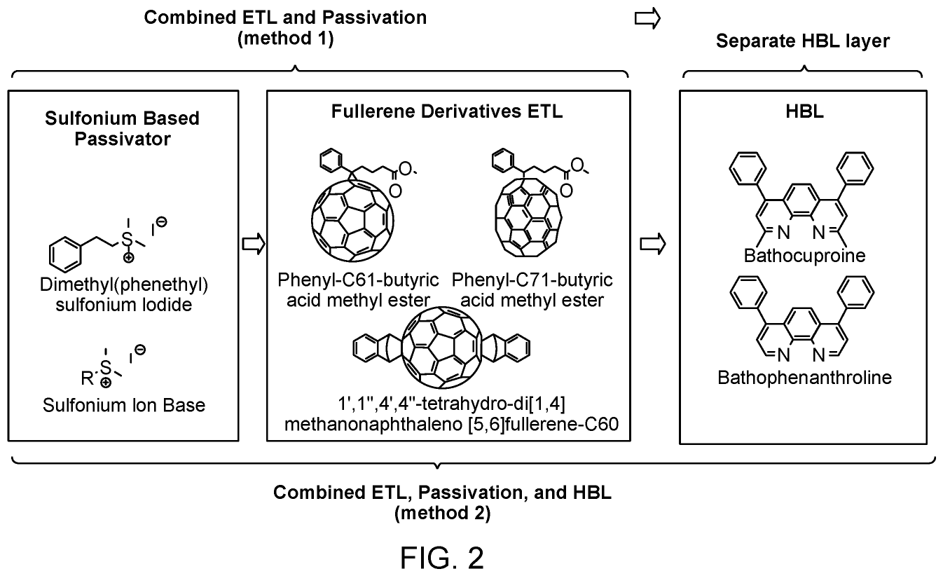

In general, it is believed that that the presence of a surface passivation layer is important for achieving high device efficiency and uniformity. In certain implementations, surface passivation can be achieved by depositing a passivation material from a solution that includes additional functional materials. For example, FIG. 2(d) conceptually depicts a method of mixing passivation, electron transport and hole blocking materials in solution. Method 1: depicts mixing two passivation and fullerene derivative in one solution and processed as a single layer, Method 2: depicts a concept of mixing three passivation, PCBM and hole blocking layer in one solution and processed as a single layer. In certain cases, chlorobenzene or Anisole can be used as solvent to dissolve materials.

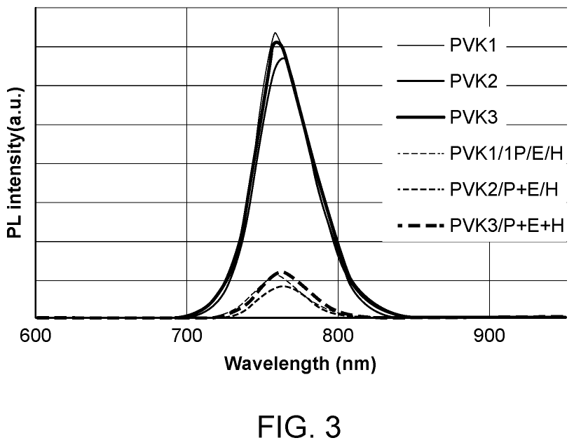

FIG. 3 shows Spatially Resolved Photoluminescence (SRPL) comparison of three different samples, in particular between (a) A conventional multilayer architecture comprising three separate solution-processed layers (P/E/H) deposited sequentially on top of the perovskite absorber layer, (b) A two-step solution-processed configuration in which a combined passivation layer and fullerene derivative base electron transport layer (E) are deposited on the perovskite absorber (PVK), followed by a separate hole-blocking layer (H), (c) A single-step solution-processed configuration comprising a mixture of passivation material (P), fullerene derivative (E), and hole-blocking layer (H) deposited together on the perovskite absorber (PVK). It can be observed that all 3-configurations demonstrated excellent quenching efficiency with the minimum change in photoluminescence quenching efficiency after adding passivation and transport layers on top of perovskite absorber. This indicates charge transfer efficiency between perovskite absorber and transport layers are similar for all three configurations.

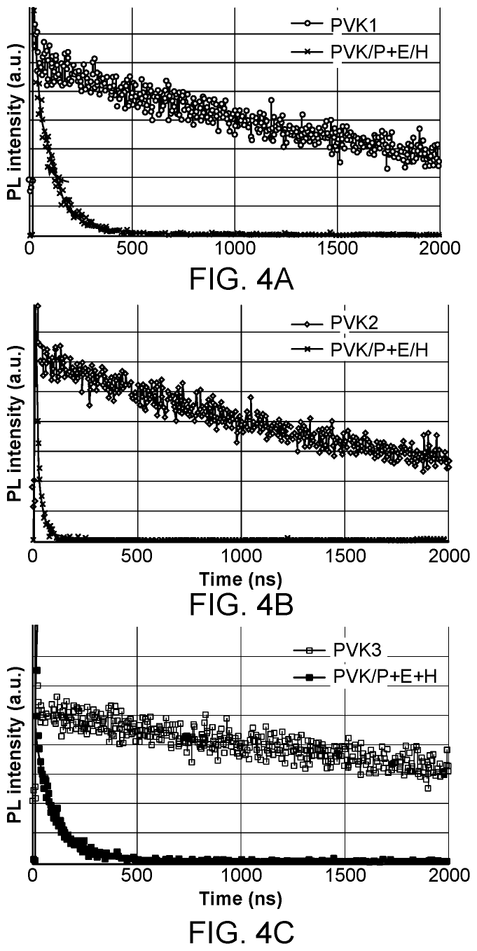

FIG. 4(a)-(c) shows a series of plots of Time Resolved Photoluminescence (TRPL) data comparing (a) A conventional multilayer architecture comprising three separate solution-processed layers deposited sequentially on top of the perovskite absorber layer, (b) A two-step solution-processed configuration in which a combined passivation layer and fullerene derivative (ETL) are deposited on the perovskite absorber (PVK), followed by a separate hole-blocking layer (HBL), (c) A single-step solution-processed configuration comprising a mixture of passivation material, fullerene derivative electron transport material, and hole-blocking layer (HBL) deposited together on the perovskite absorber (PVK), in accordance with certain example implementations of the disclosed technology. Lifetimes τ₁ and τ₂ for this data is summarized in Table 1. As shown here, for all three bare perovskite films, τ₂ shows long lifetime (2.4 to 2.9 μs, Table 1) indicates that photogenerated carrier remain within the perovskite layer. By adding conventional three-layer steps (P/E/H) architecture of transport layer on top of perovskite, τ₂ decrease in order of 100 ns indicates efficient charge transfer. The two step and single step processed layer also shows the same trend. These results provide evidence that single-step PEH layer maintains charge extraction dynamics comparable to the conventional multilayer stack.

TABLE 1

| Films | τ₁ (ns) | τ₂ (μs) |
|---|---|---|
| PVK | 6.32 | 2.8 |
| PVK/P/E/H | 4.75 | 0.11 |
| PVK | 7.79 | 2.4 |
| PVK/P + E/H | 5.85 | 0.05 |
| PVK | 6.95 | 2.9 |
| PVK/P + E + H | 5.41 | 0.11 |

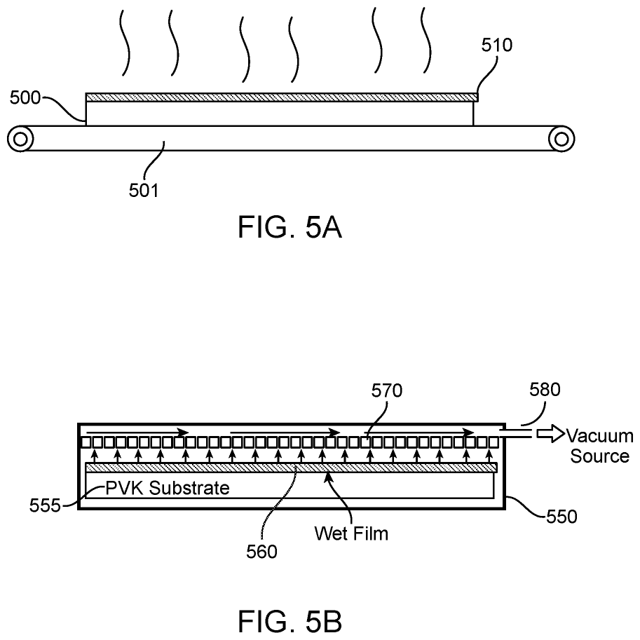

In general, PEH layers can be crystalized in a variety of ways. Referring to FIG. 5(a)-(b), two approaches to crystalizing PEH films on top of PVK layer (a) annealing approach, (b) Vacuum quenching. FIG. 5(a) shows a substrate 500 with a layer of a solution containing PEH materials on the surface of the substrate. The substrate 500 is placed on a conveyor 501 suitable for moving the substrate 500 relative to, e.g., a heat source. The heat source heats the layer 510, resulting in evaporation of the solvent from the layer and crystallization of the PEH film.

FIG. 5(b) shows, schematically, an example of a vacuum chamber 550 suitable for uniform solvent removal from a coating 560. The chamber includes a platen (not shown) that supports a coated substrate 555. A shower head vacuum manifold 570 provides uniform gas extraction across the surface of the coating. The nozzles of the shower head feed into an exhaust port 580 that is connected to a vacuum source, e.g., a pump (not shown). The nozzles can be evenly distributed across the chamber or can be arranged according to a pattern that provides a prescribed extraction profile (e.g., higher vacuum toward the center of the substrate than toward the edges, where evaporation rates are higher).

The vacuum chamber (e.g., chamber 550) can be specifically configured to facilitate uniform solvent removal from the wet film. As shown in FIG. 5(b), the chamber includes a showerhead vacuum manifold 570 positioned above the coated substrate 555. This manifold 570 features a plurality of nozzles that provide uniform gas extraction directly across the surface of the coating 560. These nozzles feed into an exhaust port 580 connected to a vacuum source, such as a high-capacity pump.

The spatial arrangement of the nozzles within the manifold 570 can be important for maintaining film uniformity across large-area substrates. In certain implementations, the nozzles are evenly distributed across the chamber to ensure a constant extraction rate. In some implementations, the nozzles are arranged according to a specific pattern to provide a prescribed extraction profile. For example, the manifold may be configured to provide a higher vacuum level toward the center of the substrate than toward the edges. This non-uniform profile can compensate for naturally higher evaporation rates at the substrate boundaries, thereby preventing “edge-effect” thickness variations and ensuring a consistent crystallization rate across the entire PEH layer.

During operation, the vacuum source reduces the internal chamber pressure below 1 atm, typically to a level between 100 Torr and 700 Torr. This reduction in pressure can effectively lower the boiling point of the solvents, such as anisole or chlorobenzene, which typically have atmospheric boiling points between 60° C. and 180° C. By tuning the vacuum level and exposure time (e.g., typically for approximately 1 minute) the system can achieve a controlled evaporation rate that yields a more uniform electron transport network compared to rapid, high-vacuum extractions at pressures like 18 Torr.

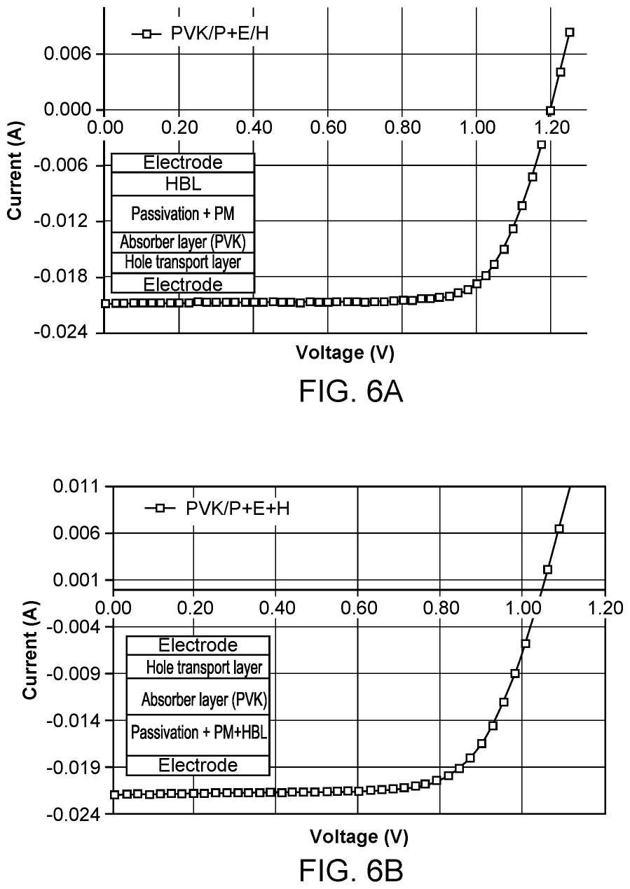

FIG. 6 depicts (a) I-V curves for two step (P+E/H) transport layer, (b) I-V curve of one step transport layer (P+E+H). Corresponding performance parameters are listed in Table 2.

TABLE 2

| Substrate name | J_{SC} (mAcm⁻²) | V_{OC} (V) | FF (%) | PCE (%) |
|---|---|---|---|---|
| PVK/P + E/H | 22.3 | 1.20 | 75.1 | 20.1 |
| PVK/P + E + H | 22.04 | 1.05 | 70.7 | 16.31 |

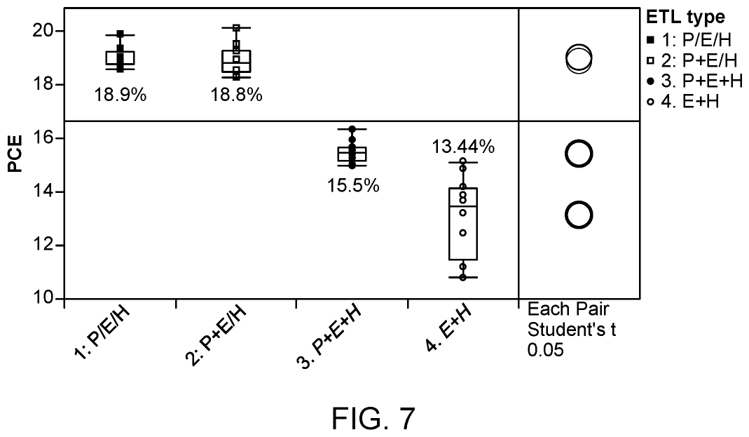

FIG. 7 shows a plot of solar cell efficiency with different configuration of passivation layer (P), electron transport layer (E) and hole blocking layer (H). 1. P/E/H: 3 separate layer coating (P/E/H), 2. P+E/H: 2 separate layer coating (P+E mixture/H), 3. 1 layer coating (P+E+H mixture), 4. 1 layer coating (E+H mixture). Average power conversion efficiencies (PCEs) calculated from more than nine devices for each configuration are reported to support and validate the findings. As illustrated in this plot, perovskite solar cells fabricated using a one-step E and H mixture without a passivation layer exhibit poor performance due to increased defect density and charge recombination. In contrast, the incorporation of P, E, and H in a single-step or two-step approach significantly enhances performance, demonstrating comparable or superior results to the conventional three-step process.

To realize short-duration uniform solvent removal over large areas, a vacuum quenching method is proposed. In this method, a vacuum is established above the wet film such that the boiling point of the film is lowered, and the subsequent evaporation rate is increased. This method can provide several advantages. First, the solvent removal can occur simultaneously across the entire area of the device given a large enough vacuum chamber. Second, avoiding traditional high temperature evaporation reduces the process flammability risks and therefore allows a potentially larger selection of solvents. Third, the solvent extraction using a vacuum quenching method could be a quicker process thereby increasing production throughput.

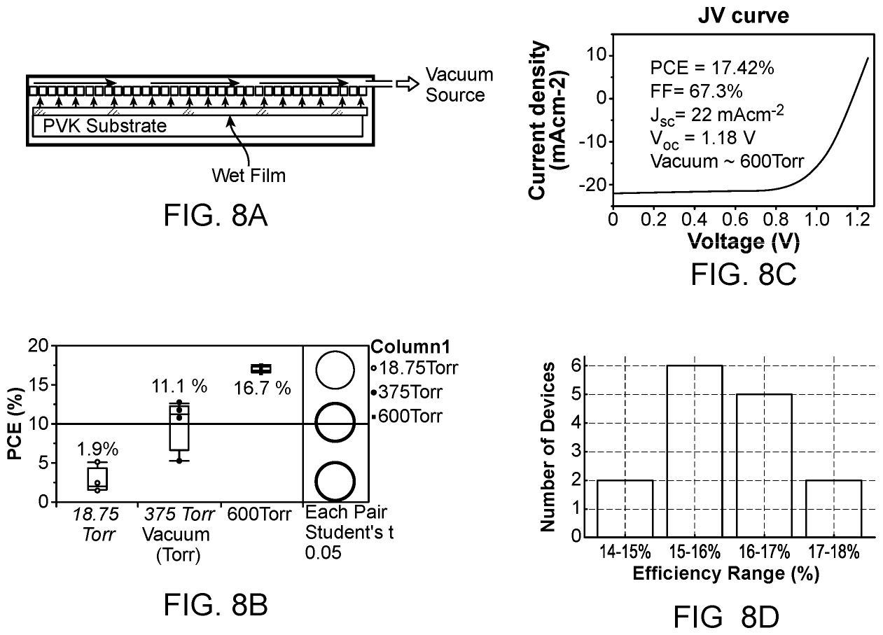

FIG. 8(a) is a schematic illustration of the scalable vacuum-quenching approach used to crystallize the one-step PEH layer described previously. FIG. 8(b) is a plot showing solar cell efficiency as a function of vacuum pressure applied during the crystallization of the one-step PEH layer. FIG. 8(c) is a plot showing champion device efficiency obtained at an optimized vacuum pressure of 600 Torr during the vacuum-quenching process. FIG. 8(d) is a plotted statistical distribution of power conversion efficiency for 20 devices fabricated using the optimized 600 Torr vacuum-quenching pressure. To demonstrate this solvent removal technique, electron transport layer (ETL) wet films were processed (using anisole as the representative solvent) over perovskite absorbers. The wet films were placed in a vacuum chamber for 1 minute in each case, and the level of the applied vacuum was varied. The devices were then processed into complete solar cells, and the conversion efficiency of the cells was measured. During operation, the pump removed air (and/or other gas) from the vacuum chamber and reduced pressure below 1 atm in the chamber, facilitating removal of the solvent from the wet film.

Generally, the vacuum level and time in the chamber can be determined empirically and can depend on the composition of the coating solution and the size of the substrate, among other factors. The vacuum level can be in a range from 1 Torr to 700 Torr, e.g., 10 Torr to 700 Torr, e.g., 100 Torr to 700 Torr, e.g., 500 Torr to 700 Torr, e.g., about 600 Torr. The coating can have a surface area in a range from 0.5 m² to 10 m², e.g., 1 m² to 5 m², e.g., 2 m² to 3 m². The temperature in the chamber can be room temperature, or the chamber can be heated or cooled.

The amount of time the substrate is exposed to vacuum can also vary and can be determined empirically. Generally, vacuum exposure can be in a range from 10 seconds to 10 minutes (e.g., 20 seconds or more, 30 seconds or more, 1 minute or more, 5 minutes or less, 2 minutes or less). Shorter times can increase overall throughput.

Typical solvents used in solution-processed carrier transport layers include (but not limited to) anisole, chlorobenzene, dichlorobenzene, toluene, and chloroform. These solvents have relatively low boiling points (at atmospheric pressure) ranging from 60° C. to 180° C. Therefore, moderate levels of vacuum can reduce the boiling points and increase evaporation relative to atmospheric pressure.

To demonstrate this solvent removal technique, two step layer (P+E/H) wet films were processed (using anisole as the representative solvent) over perovskite absorbers. The wet films were placed in a vacuum chamber for 1 minute in each case at a constant vacuum level. The level of the applied vacuum was varied for different samples. The devices were then processed into complete solar cells, and the conversion efficiency of the cells was measured. As shown in FIG. 8(b), higher vacuum levels (18 Torr) resulting in poorer solar cell efficiency than lower vacuum levels (600 Torr). It is believed that the rapid removal of solvent during the 1 minute vacuum duration reduced uniformity of the resulting ETL, whereas slower removal yielded a more uniform extraction, hence a more uniform ETL, and a higher solar cell efficiency. As shown in FIG. 8(c), the optimized 600 Torr vacuum condition yields a peak power conversion efficiency (PCE) of 17.5%. Furthermore, the narrow efficiency distribution of 20 devices shown in FIG. 8(d) confirms the reproducibility of this processing method.

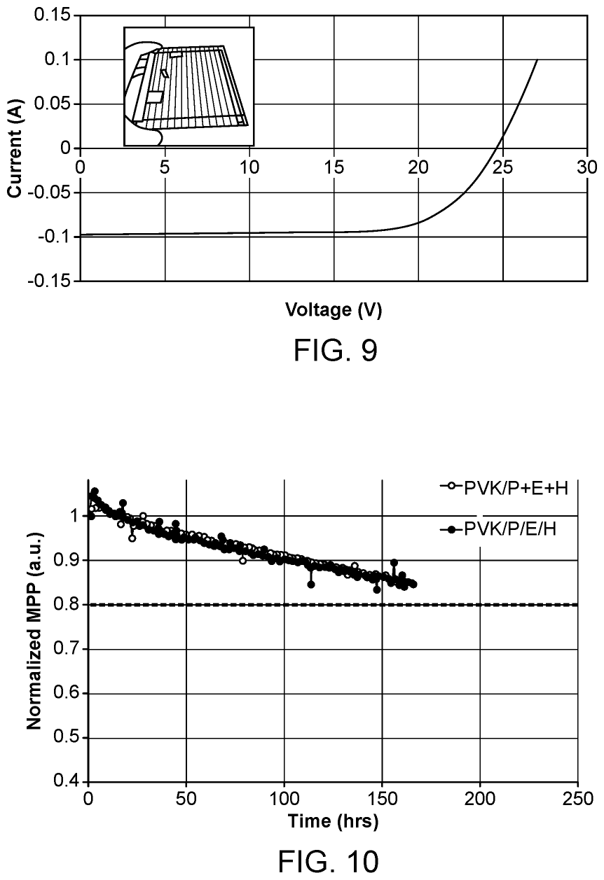

FIG. 9 is a plot showing performance of a mini-module with a single-step PEH layer with an active area of 110.3 cm², confirming that the one-step layer configuration enables improved charge extraction Device performance parameters are shown in Table 3.

TABLE 3

| Substrate name | J_{SC} (mAcm⁻²) | V_{OC} (V) | FF (%) | PCE (%) |
|---|---|---|---|---|
| D1-1908, R2C10 | 0.938 | 24.51 | 71.1 | 16.34 |

Furthermore, module reliability tests were performed at 75° C. under 1 sun illumination for both the standard three-step configuration (P/E/H) and the single-step configuration (P+E+H). FIG. 10 is a plot showing mini module (active area=110.3 cm²) reliability comparison between standard separate layer (P/E/H, green) and one step mixed layer (P+E+H, blue) coated on top of PVK layer. The results indicate that the one-step layer, composed of a mixture of passivation, fullerene derivative, and hole-blocking layer, exhibits slightly improved thermal stability. Without wishing to be bound by theory, this enhanced stability is attributed to the reduced dimerization of the fullerene derivative and suppressed triplet-to-singlet recombination processes.

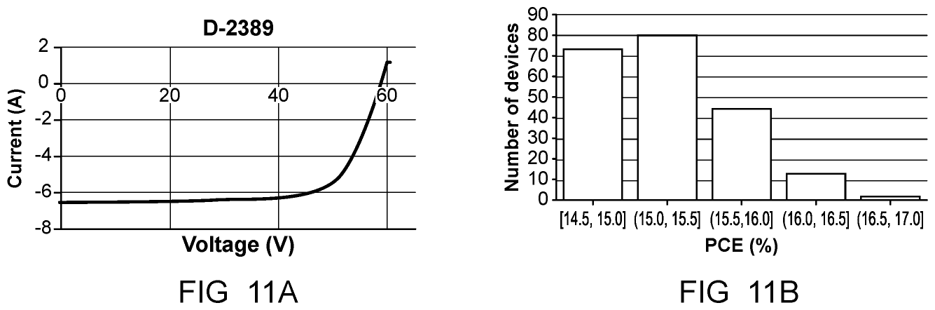

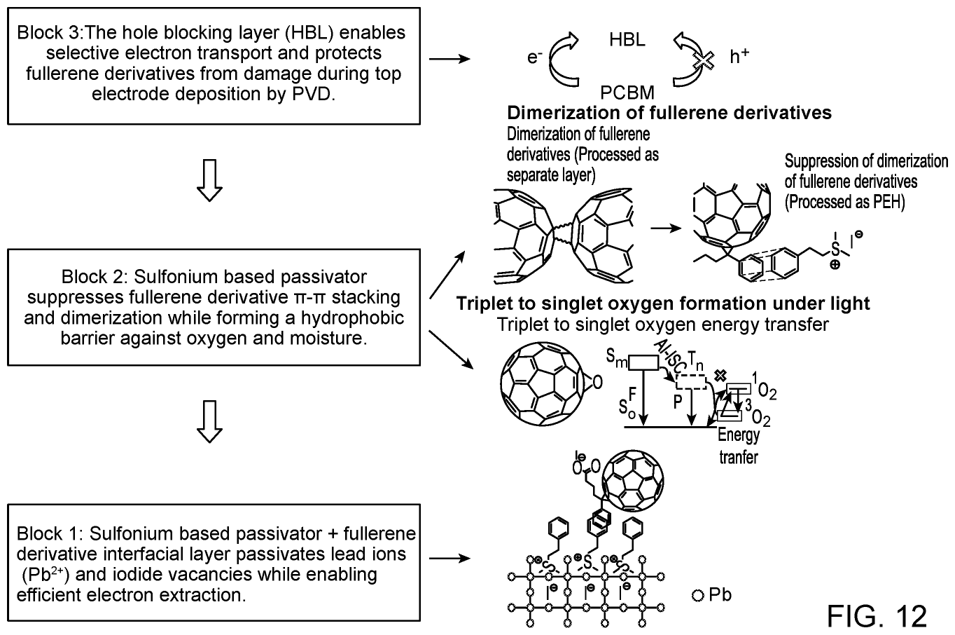

FIG. 11(a) is a plot showing an I-V curve of an industrial-scale perovskite module with a single-step PEH layer (active area: 1.7192 m²). FIG. 11(b) is a PCE distribution plot for multiple panels processed using the single-step PEH layer. The detailed performance parameters corresponding to FIG. 11(a) are listed in Table 4. These results demonstrate the high reproducibility of achieving elevated efficiencies in panels with the one-step PEH layer, providing strong evidence that this approach enables both high-efficiency and consistently reproducible industrial-scale modules.

TABLE 4

| | Pmax | PCE | FF | | | R_{SH} | R_{S} |
|---|---|---|---|---|---|---|---|
| Substrate ID | (W) | (%) | (%) | I_{SC} | V_{OC} | (Ω) | (Ω) |
| D1-2389 | 278.69 | 16.21 | 72.3 | 6.5476 | 58.9 | 330.7 | 1 |

Referring to FIG. 12, the single step PEH method according to an example implementation of the disclosed perovskite solar cell technology can be represented in a three-block flow diagram.

Block 1: Simultaneous Surface Passivation and Electron Extraction Mixing sulfonium based passivator with fullerene derivative: The sulfonium-based passivation molecule chemically passivates under-coordinated Pb²⁺ sites and iodide vacancies at the perovskite surface through Lewis acid-base and ionic interactions. Simultaneously, fullerene derivative forms a percolated electron transport pathway that enables efficient electron extraction from the perovskite absorber. The combined sulfonium passivation-fullerene derivative interfacial layer therefore provides dual functionality: chemical defect passivation and efficient electron transport, reducing surface trap density, suppressing non-radiative recombination, maintaining efficient charge collection, and reduced interfacial energy barriers. This is demonstrated in FIG. 3 and FIG. 4, described previously.

Further, sulfonium-based passivation modifies the surface dipole and electronic structure of the perovskite. When co-deposited with fullerene derivatives, the interfacial energy alignment between perovskite and fullerene derivative is improved. Electron extraction becomes more favorable. Interfacial band bending can be optimized. Single-solution deposition can provide more uniform wetting of the perovskite surface, improved fullerene derivative film continuity, and reduced pinholes compared to conventional methods. Better grain boundary coverage of passivation layer (sulfonium based passivation) can act as a surface energy modifier and morphology regulator for fullerene derivative crystallization/aggregation. This enhances interfacial conformity, mechanical robustness, and device reproducibility.

Block 2: Suppression of Ion Migration at the ETL Interface and Enhanced Moisture and Environmental Stability: Sulfonium based passivation chemically binds to perovskite surface sites, which: stabilizes iodide and lead species, reduces mobile ionic defects, and mitigates ion migration toward the ETL. When blended within fullerene derivative, the passivation effect is maintained while forming a physical diffusion barrier, reducing interfacial degradation under bias and illumination. This improves operational stability, light-soaking stability, and thermal stability, which is demonstrated in FIG. 10, described above.

Sulfonium base passivation also increases surface hydrophobicity. When incorporated into fullerene derivative, the mixed ETL becomes more moisture resistant. Water penetration into the perovskite is reduced. Interfacial degradation is suppressed. This is particularly advantageous compared to pure fullerene derivative layers process separately.

The bulky benzyl-substituted sulfonium base passivation molecules (For example, DMPESI) introduce steric hindrance that disrupts π-π stacking between adjacent fullerene derivative molecules, thereby inhibiting thermally or photo-induced fullerene derivative dimerization. By disrupting the π-π stacking of the fullerene derivatives, the sulfonium-based molecules prevent the formation of fullerene dimers that would otherwise create charge traps and degrade the module's fill factor over time. In addition, the passivation layer used in this study forms a hydrophobic interfacial barrier, limiting oxygen and moisture diffusion toward the fullerene layer. Reduced oxygen exposure suppresses triplet-mediated singlet oxygen formation, thereby improving the photochemical stability of the fullerene electron transport network.

Block 3: Built-in Hole Blocking Function: The synergy between passivation+electron transport+hole blocking (HBL) in a single layer is likely non-obvious compared to conventional three or four layer Passivation/ETL/HBL stacks. This creates a graded multifunctional interfacial layer that enhances electron selectivity, suppresses hole leakage, reduces interfacial recombination current, and increases fill factor. HBL materials such as Bathocuproine (BCP) or Bathophenanthroline (BPhen) also protect the underlying ETL from direct interaction with the metal electrode, preserving favorable energy level alignment, and enabling efficient charge extraction at the cathode interface. In addition, the HBL acts as a protective buffer during physical vapor deposition (PVD) of the top electrode, mitigating plasma- or energetic particle-induced damage to the ETL layer. For example, the hole-blocking component of the single-step layer can provide a physical and electronic buffer that prevents the penetration of energetic metal atoms or plasma species into the fullerene-based ETL during PVD, thereby maintaining the integrity of the ETL's energy level alignment.

Simplified Manufacturing Process: The single-step mixed solution process provides reduced processing steps, lower manufacturing cost, reduced solvent exposure of the perovskite layer, better compatibility with roll-to-roll coating/slot die coating/blade coating/spray coating, compared to sequential deposition fewer alignment and solvent orthogonality issues improved scalability and reduced interlayer dissolution risk.

This approach addresses the scalability issue by simplifying the coating process to a single step while maintaining or improving device performance. In addition, PEH layer serves to simultaneously passivate the surface of the perovskite material, enhance electron transport, and block holes, thereby improving device performance and reducing degradation over time.

A number of embodiments are described. Other embodiments are in the claims.

1. A method for forming a perovskite solar cell, comprising:
depositing a mixture comprising a sulfonium-based passivation material, a fullerene derivative, and a hole-blocking material on a surface of a substrate comprising a perovskite layer to form a single-step multifunctional layer; and
further processing the substrate and the single-step layer to form a perovskite solar cell.

2. The method of claim 1, wherein the sulfonium-based passivation chemically passivates under-coordinated lead sites and halide vacancies in the perovskite layer.

3. The method of claim 1, wherein the fullerene derivative forms a percolated electron transport pathway for efficient electron extraction from the perovskite absorber.

4. The method of claim 1, wherein the hole-blocking material is selected from the group consisting of BCP, BPhen, or derivatives thereof.

5. The method of claim 1, wherein the mixture is dissolved in one or more organic solvents selected from anisole, chlorobenzene, dichlorobenzene, toluene, or chloroform.

6. The method of claim 1, wherein the mixture is deposited using a solution-processing technique selected from spin coating, slot-die coating, blade coating, spray coating, or roll-to-roll coating.

7. The method of claim 1, further comprising exposing the deposited mixture to a vacuum to control solvent evaporation, wherein the vacuum pressure is in a range of 1 Torr to 700 Torr.

8. The method of claim 7, wherein the vacuum is applied uniformly across the coating or according to a spatial extraction profile to achieve uniform film formation.

9. The method of claim 7, wherein the vacuum is applied via a showerhead manifold comprising a plurality of nozzles arranged to provide a non-uniform spatial extraction profile to compensate for edge-effect evaporation.

10. The method of claim 1, wherein the processing further comprises thermal annealing of the deposited layer to improve crystallinity of the electron transport and passivation mixture.

11. The method of claim 1, wherein the deposition and processing of the single-step layer simultaneously provides: surface passivation of the perovskite layer, electron extraction, and hole-blocking functionality.

12. The method of claim 1, wherein the single-step layer reduces dimerization of the fullerene derivative and suppresses triplet-to-singlet recombination at the interface.

13. The method of claim 1, further comprising forming a top electrode by physical vapor deposition (PVD), wherein the single-step layer protects the electron transport layer from plasma-induced damage during electrode deposition.

14. A perovskite solar cell, comprising:
a perovskite absorber layer;
a single-step interfacial layer deposited on the perovskite absorber, comprising a sulfonium-based passivation material, a fullerene derivative, and a hole-blocking material; and
an electrode deposited on the single-step layer,
wherein the single-step layer simultaneously provides chemical passivation, electron transport, and hole blocking.

15. The perovskite solar cell of claim 13, wherein the single-step layer forms a hydrophobic interfacial barrier.

16. The perovskite solar cell of claim 13, wherein the single-step layer suppresses ion migration at the ETL interface, improving operational and light-soaking stability.

17. The perovskite solar cell of claim 13, wherein the hole-blocking material forms a protective buffer between the electron transport layer and the top electrode sufficient to reduce plasma- or energetic particle-induced damage.

18. The perovskite solar cell of claim 13, wherein the active area of the perovskite solar cell is at least 100 cm².
